(19) United States
(12) Patent Application Publication
(10) Pub. No.: US 2025/0273155 A1
(43) Pub. Date: Aug. 28, 2025

(54) DISPLAY DEVICE

(71) Applicant: LG Display Co., Ltd., Seoul (KR)

(72) Inventor: Taehwi KIM, Paju-si (KR)

(73) Assignee: LG Display Co., Ltd., Seoul (KR)

(21) Appl. No.: 19/021,829

(22) Filed: Jan. 15, 2025

(30) Foreign Application Priority Data
Feb. 26, 2024 (KR) 10-2024-0027379

(51) Int. Cl. G09G 3/3241

(52) U.S. Cl. CPC G09G 3/3241; G09G 2300/0426; G09G 2300/0819; G09G 2300/0842; G09G 2300/0861; G09G 2310/08; G09G 2320/0233; G09G 2330/021; G09G 2340/0435

(57) ABSTRACT

In one or more examples, a display device includes a display panel including an active area in which one or more optical areas are disposed; and one or more sensor modules overlapped with the one or more optical areas. The one or more optical areas may be divided into a pixel area in which a plurality of pixels is disposed and a transmissive area through which light of the one or more sensor modules is to pass. Among a plurality of constant power lines configured to apply at least one constant power to the plurality of pixels disposed in the pixel area, adjacent constant power lines may be connected to each other.

### CROSS-REFERENCE TO RELATED APPLICATIONS

This application claims the benefit of and priority to Korean Patent Application No. 10-2024-0027379 filed on Feb. 26, 2024, in the Korean Intellectual Property Office, the entire contents of which are incorporated herein by reference for all purposes.

### BACKGROUND

### 1. Technical Field

The present disclosure relates to a display device, and particularly to, for example, without limitation, a display device in which a sensor is disposed below an active area.

### 2. Description of the Related Art

Recently, as it enters an information era, a display field which visually expresses electrical information signals has been rapidly developed and in response to this, various display devices having excellent performances such as thin-thickness, light weight, and low power consumption have been developed.

Unlike a liquid crystal display device (LCD) which includes a backlight, among them, an organic light emitting display device (OLED) does not require a separate light source. Therefore, the organic light emitting display device may be manufactured to be light and thin and has process advantages and has low power consumption in accordance with the low voltage driving. First of all, the organic light emitting display device includes a self-emitting element and includes layers formed of organic thin films so that the flexibility and elasticity are superior to the other display devices and thus it is advantageous to be implemented as a flexible display device or a transparent display device.

In the meantime, the display device has an active area in which images are substantially displayed and a bezel area which is a non-active area which is blocked by a light shielding member so that images are not substantially displayed. In the active area, a display element is disposed to display images and in the bezel area, various wiring lines or driving circuits for driving the display element are disposed. The display device includes a camera, a speaker, and various sensors to provide various functions and these components are also disposed in the bezel area.

In recent years, in order to make the design of the display device beautiful and provide a larger screen in a limited size of the display device as large as possible, studies to reduce the bezel area are actively being conducted. In accordance with this, components, such as a camera or a sensor, which have been disposed in the bezel area in the related art are disposed in an optical area of the active area, but in order to smoothly display images, a technique which disposes the components on a rear surface of the display panel is being proposed.

The description of the related art should not be assumed to be prior art merely because it is mentioned in or associated with this section. The description of the related art includes information that describes one or more aspects of the subject technology, and the description in this section does not limit the invention.

### SUMMARY

An aspect of the present disclosure is to provide a display device which ensures the transmittance of an optical area.

An aspect of the present disclosure is to provide a display device which reduces a deviation of a constant power input to a plurality of pixels.

Still another aspect of the present disclosure is to provide a display device which ensures luminance uniformity.

Aspects of the present disclosure are not limited to the above-mentioned aspects, and other aspects, which are not mentioned above, can be clearly understood by those skilled in the art from the disclosure herein, including the drawings.

In order to achieve the aspects as described above, according to one or more examples of the present disclosure, a display device includes a display panel including an active area in which one or more optical areas are disposed; and one or more sensor modules overlapped with the one or more optical areas, the one or more optical areas are divided into a pixel area in which a plurality of pixels is disposed and a transmissive area through which light of the one or more sensor modules is to pass, and among a plurality of constant power lines configured to apply at least one constant power to the plurality of pixels disposed in the pixel area, adjacent constant power lines may be connected to each other.

Other detailed matters of the example embodiments are included in the detailed description and the drawings.

According to one or more aspects of the present disclosure, a bias voltage, a reset voltage, or an initialization voltage which is a uniform constant power can be applied to a plurality of pixels disposed in an optical area to ensure a luminance uniformity of the optical area.

According to one or more aspects of the present disclosure, even though a constant power line is connected, the degradation of transmittance may be suppressed.

The effects of the present disclosure are not limited to the aforementioned effects, and other effects, which are not mentioned above, will be apparently understood to a person having ordinary skill in the art from the following description.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a block diagram schematically illustrating a display device according to an example embodiment of the present disclosure;

FIG. 2 is a cross-sectional view illustrating a laminated structure of a display device according to an example embodiment;

FIG. 3 is a view of a configuration of a gate driver in a display device according to an example embodiment of the present disclosure;

FIG. 4 is a view for a pixel circuit in a display device according to an example embodiment of the present disclosure;

FIGS. 5A and 5B are views for explaining an operation of a scan signal and an emission control signal in a refresh period and a hold period in a pixel circuit illustrated in FIG. 4;

FIGS. 6A and 6B are views for explaining a placement relationship of a plurality of constant power lines when an optical area of a display device according to an example embodiment of the present disclosure is disposed in the center;

FIGS. 7A and 7B are views for explaining a placement relationship of a plurality of constant power lines when an optical area of a display device according to an example embodiment of the present disclosure is disposed at one side;

FIGS. 8A and 8B are views for explaining a placement relationship of a plurality of constant power lines when an optical area of a display device according to an example embodiment of the present disclosure is disposed at the other side;

FIG. 9 is a view for explaining a connection relationship of a plurality of sub lines of a display device according to an example embodiment of the present disclosure;

FIG. 10 is a view for explaining a placement relationship of a plurality of sub lines and a connection line of a display device according to an example embodiment of the present disclosure; and

FIG. 11 is a view for explaining a placement relationship of a plurality of sub lines and a connection line of a display device according to another example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. Any references to singular may include plural unless expressly stated otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate (ly),” or “direct (ly),” is used.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) multiple elements of the plurality of elements, or (v) all of the plurality of elements. Moreover, “at least some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, or (iii) the element, or all portions of the element.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

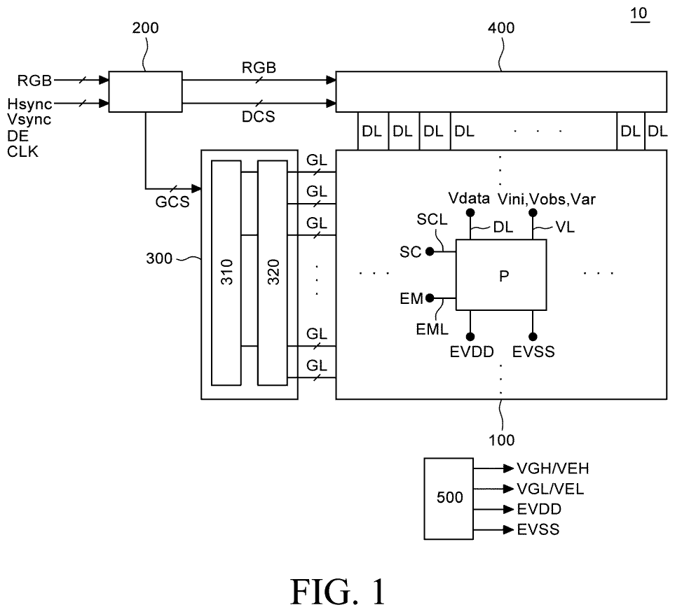

FIG. 1 is a block diagram schematically illustrating a display device according to an example embodiment of the present disclosure.

Referring to FIG. 1, the display device 10 includes a display panel 100 including a plurality of pixels P, a controller 200, a gate driver 300 configured to supply a gate signal to each of the plurality of pixels P, a data driver 400 configured to supply a data signal to each of the plurality of pixels P, and a power supply unit 500. The power supply unit 500 supplies the power required for driving to each of the plurality of pixels P.

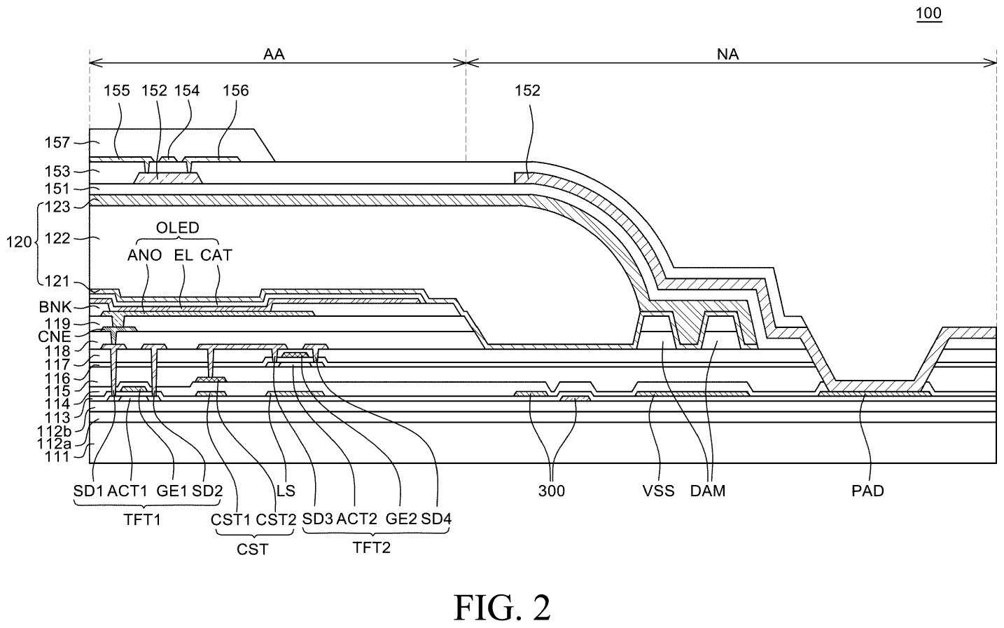

The display panel 100 includes an active area AA (see FIG. 2) in which the pixel P is located and a non-active area NA (see FIG. 2) which is disposed so as to enclose the active area AA and includes the gate driver 300 and the data driver 400.

In the display panel 100, the plurality of gate lines GL and the plurality of data lines DL intersect each other and the plurality of pixels P is connected to the gate lines GL and the data line DL, respectively. Specifically, one pixel P is supplied with a gate signal from the gate driver 300 through the gate line GL, is supplied with a data signal from the data driver 400 through the data line DL, and is supplied with a high potential driving voltage EVDD and a low potential driving voltage EVSS from the power supply unit 500.

Here, the gate line GL supplies a scan signal SC and an emission control signal EM and the data line DL supplies a data voltage Vdata. Further, according to various example embodiments, the gate line GL may include a plurality of gate lines SCL configured to supply a scan signal SC and an emission control signal line EML configured to supply the emission control signal EM. Further, the plurality of pixels P further includes a power line VL to be supplied with a bias voltage Vobs and initialization voltages Var and Vini.

Further, each pixel P includes a light emitting diode OLED and a pixel circuit which controls the operation of the light emitting diode OLED, as illustrated in FIG. 2. Here, the light emitting diode OLED is configured by an anode electrode ANO, a cathode electrode CAT, and an emission layer EL between the anode electrode ANO and the cathode electrode CAT.

The pixel circuit includes a plurality of switching elements, a driving element, and a capacitor. Here, the switching element and the driving element may be configured by thin film transistors. In the pixel circuit, the driving element controls an amount of currents to be supplied to the light emitting diode OLED in accordance with the data voltage to adjust an emission amount of the light emitting diode OLED. Further, the plurality of switching elements receives a scan signal SC supplied through the plurality of gate lines SCL and an emission control signal EM supplied through the emission control line EML to operate the pixel circuit.

The display panel 100 may be implemented as a non-transmissive display panel or a transmissive display panel. The transmissive display panel may be applied to a transparent display device in which an image is displayed on a screen and real objects in the background are visible. The display panel 100 may be manufactured as a flexible display panel. The flexible display panel may be implemented by an OLED panel which uses a plastic substrate.

Each pixel P may be divided into a red pixel, a green pixel, and a blue pixel to implement colors. Each pixel P may further include a white pixel. Each pixel P includes a pixel circuit.

Touch sensors may be disposed on the display panel 100. The touch input is sensed using separate touch sensors or sensed by pixels P. The touch sensors are disposed on the screen of the display panel in an on-cell type or an add-on type or implemented as in-cell type touch sensors to be embedded in the display panel 100.

The controller 200 processes image data RGB input from the outside to be suitable for a size and a resolution of the display panel 100 to supply the processed image data to the data driver 400. The controller 200 generates a gate control signal GCS and a data control signal DCS using synchronization signals input from the outside, for example, a dot clock signal CLK, a data enable signal DE, a horizontal synchronization signal Hsync, and a vertical synchronization signal Vsync. The generated gate control signal GCS and data control signal DCS are supplied to the gate driver 300 and the data driver 400, respectively, to control the gate driver 300 and the data driver 400.

The controller 200 may be configured to be coupled with various processors, such as a microprocessor, a mobile processor, or an application processor, depending on a device to be mounted.

A host system may be any one of a television (TV) system, a set top box, a navigation system, a personal computer (PC), a home theater system, a mobile device, a wearable device, and a vehicle system.

The controller 200 multiples an input frame frequency by i and may control an operating timing of a display panel driver with a frame frequency of an input frame frequency x i (i is a positive integer larger than 0) Hz. The input frame frequency is 60 Hz in a national television standards committee (NTSC) standard and is 50 Hz in a phase-alternating line (PAL) standard.

The controller 200 generates a signal to allow the pixel P to be driven at various refresh rates. That is, the controller 200 generates signals associated with the driving to allow the pixel P to be driven in a variable refresh rate (VRR) mode or to be switchable between a first refresh rate and a second refresh rate. For example, the controller 200 may drive the pixel P at various refresh rates by simply changing a rate of a clock signal, or generating a synchronization signal to generate a horizontal blank or a vertical blank, or driving the gate driver 300 in a mask manner.

The controller 200 generates a gate control signal GCS for controlling an operating timing of the gate driver 300 and a data control signal DSC for controlling an operating timing of the data driver 400, based on timing signals Vsync, Hsync, and DE received from the host system. The controller 200 controls the operating timing of the display panel driver to synchronize the gate driver 300 and the data driver 400.

A voltage level of the gate control signal GCS output from the controller 200 is converted into gate-on voltages VGL and VEL and gate-off voltages VGH and VEH through a level shifter which is not illustrated to be supplied to the gate driver 300. The level shifter converts a low level voltage of the gate control signal GCS into the gate low voltage VGL and converts a high level voltage of the gate control signal GCS into a gate high voltage VGH. The gate control signal GCS includes a start pulse and a shift clock.

The gate driver 300 supplies the scan signals SC to the gate lines GL in accordance with the gate control signal GCS supplied from the controller 200. The gate driver 300 may be disposed at one side or both sides of the display panel 100 in a gate in panel (GIP) manner.

The gate driver 300 sequentially outputs the gate signals to the plurality of gate lines GL under the control of the controller 200. The gate driver 300 shifts the gate signal using a shift register to sequentially supply the signals to the gate lines GL.

The gate signal may include a scan signal SC and an emission control signal EM in the organic light emitting display device. The scan signal SC includes a scan pulse swinging between the gate-on voltage VGL and the gate-off voltage VGH. The emission control signal EM may include an emission control signal pulse swinging between the gate-on voltage VEL and the gate-off voltage VEH.

The scan pulse is synchronized with the data voltage Vdata to select the pixels P of a line in which the data is written. The emission control signal EM defines an emission time of the pixels P.

The gate driver 300 may include an emission control signal driver 310 and at least one or more scan drivers 320.

The emission control signal driver 310 outputs an emission control signal pulse in response to a start pulse and a shift clock from the controller 200 and sequentially shifts the emission control signal pulse in accordance with a shift clock.

At least one or more scan drivers 320 output the scan pulse in response to a start pulse and a shift clock from the controller 200 and shift a scan pulse in accordance with the shift clock timing.

The data driver 400 converts image data RGB into a data voltage Vdata in accordance with the data control signal DCS supplied from the controller 200 and supplies the converted data voltage Vdata to the pixel P through the data line DL.

Even though in FIG. 1, it is illustrated that one data driver 400 is disposed at one side of the display panel 100, the number of the data drivers 400 and a placement position thereof are not limited thereto.

That is, the data driver 400 is configured by a plurality of integrated circuits (IC) to be divided into a plurality of parts at one side of the display panel 100.

The power supply unit 500 generates a DC power required to drive the pixel array of the display panel 100 and the display panel driver using a DC-DC converter. The DC-DC converter may include a charge pump, a regulator, a buck converter, a boost converter, and the like. The power supply unit 500 receives a DC input voltage applied from the host system which is not illustrated to generate a DC voltage, such as a gate-on voltage VGL and VEL, a gate-off voltage VGH and VEH, a high potential driving voltage EVDD, and a low potential driving voltage EVSS. The gate-on voltage VGL and VEL and the gate-off voltage VGH and VEH are supplied to the level shifter which is not illustrated and the gate driver 300. The high potential driving voltage EVDD and the low potential driving voltage EVSS are commonly supplied to the pixels P.

FIG. 2 is a cross-sectional view illustrating a laminated structure of a display device according to an example embodiment.

Referring to FIG. 2, FIG. 2 is a cross-sectional view including two switching thin film transistors TFT1 and TFT2 and one storage capacitor Cst. Two thin film transistors TFT1 and TFT2 include any one thin film transistor, of a switching thin film transistor or a driving transistor including a polycrystalline semiconductor material, and an oxide thin film transistor TFT2 including an oxide semiconductor material. In this case, the thin film transistor including the polycrystalline semiconductor material is referred to as a polycrystalline thin film transistor TFT1 and the thin film transistor including the oxide semiconductor material is referred to as an oxide thin film transistor TFT2.

The polycrystalline thin film transistor TFT1 illustrated in FIG. 2 is an emission switching thin film transistor connected to the light emitting diode OLED and the oxide thin film transistor TFT2 is any one switching thin film transistor connected to the storage capacitor Cst.

One pixel P includes the light emitting diode OLED and a pixel driving circuit configured to apply a driving current to the light emitting diode OLED. The pixel driving circuit is disposed on the substrate 111 and the light emitting diode OLED is disposed on the pixel driving circuit. Further, an encapsulation layer 120 is disposed on the light emitting diode OLED. The encapsulation layer 120 protects the light emitting diode OLED.

The pixel driving circuit may refer to one pixel (P) array unit including a driving thin film transistor, a switching thin film transistor, and a capacitor. Further, the light emitting diode OLED may refer to an array unit which includes an anode electrode and a cathode electrode and an emission layer disposed therebetween to emit light.

In one example embodiment, the driving thin film transistor and at least one switching thin film transistor use the oxide semiconductors as active layers. The thin film transistor which uses the oxide semiconductor material as an active layer has an excellent leakage current blocking effect and has a manufacturing cost which is relatively cheaper than a thin film transistor which uses a polycrystalline semiconductor material as an active layer. Accordingly, in order to reduce the power consumption and save the manufacturing cost, the pixel driving circuit according to the example embodiment includes a driving thin film transistor and at least one switching thin film transistor which use the oxide semiconductor material.

All the thin film transistors which configure the pixel driving circuit may be implemented using the oxide semiconductor material or only some switching thin film transistor may be implemented using the oxide semiconductor material.

However, it is difficult to ensure the reliability with the thin film transistor using the oxide semiconductor material, but the thin film transistor using a polycrystalline semiconductor material has a rapid operation speed and excellent reliability. Accordingly, the example embodiment includes both the switching thin film transistor using the oxide semiconductor material and the switching thin film transistor using a polycrystalline semiconductor material.

The substrate 111 may be configured as a multi-layer in which an organic film and an inorganic film are alternately laminated. For example, in the substrate 111, an organic film such as polyimide and an inorganic film such as silicon oxide (SiO₂) may be alternately laminated.

A lower buffer layer 112a is formed on the substrate 111. The lower buffer layer 112a is provided to block moisture penetrating from the outside and may be used by laminating a plurality of silicon oxide (SiO₂) films. An auxiliary buffer layer 112b may be further disposed on the lower buffer layer 112a to protect the element from the moisture permeation.

The polycrystalline thin film transistor TFT1 is formed on the substrate 111. The polycrystalline thin film transistor TFT1 may use the polycrystalline semiconductor as an active layer. The polycrystalline thin film transistor TFT1 includes a first active layer ACT1 including a channel through which electrons or holes move, a first gate electrode GE1, a first source electrode SD1, and a first drain electrode SD2.

The first active layer ACT1 includes a first channel area, a first source area which is disposed at one side of the first channel area and a first drain area disposed at the other side. The first source area and the first drain area are disposed with the first channel area therebetween.

The first source area and the first drain area are areas in which an intrinsic polycrystalline semiconductor material is doped with group 5 or group 3 impurity ions, for example, phosphorus (P) or boron (B) at a predetermined concentration to be conductive. In the first channel area, the polycrystalline semiconductor material maintains an intrinsic state and a path through which the electrons or holes move is provided.

In the meantime, the polycrystalline thin film transistor TFT1 includes a first gate electrode GE1 which overlaps the first channel area of the first active layer ACT1. A first gate insulating layer 113 is disposed between the first gate electrode GE1 and the first active layer ACT1. The first gate insulating layer 113 may be used by laminating inorganic layers, such as a silicon oxide (SiO₂) film or silicon nitride (SiNₓ) as a single layer or a plurality of layers.

In the example embodiment, the polycrystalline thin film transistor TFT1 has a top gate structure in which the first gate electrode GE1 is located above the first active layer ACT1. Accordingly, a first electrode CST1 included in a storage capacitor Cst and a light shielding layer LS included in the oxide thin film transistor TFT2 may be formed with the same material as the first gate electrode GE1. The first gate electrode GE1, the first electrode CST1, and the light shielding layer LS are formed by one mask process so that the number of mask processes may be reduced.

The first gate electrode GE1 is configured by a metal material. For example, the first gate electrode GE1 may be a single layer or a plurality of layers formed of any one of molybdenum (Mo), aluminum (Al), chrome (Cr), gold (Au), titanium (Ti), nickel (Ni), neodymium (Nd), and copper (Cu) or an alloy thereof, but is not limited thereto.

A first interlayer insulating layer 114 is disposed on the first gate electrode GE1. The first interlayer insulating layer 114 may be configured by silicon oxide (SiO₂) or silicon nitride (SiNₓ).

The display panel 100 may further include an upper buffer layer 115, a second gate insulating layer 116, and a second interlayer insulating layer 117 which are sequentially disposed on the first interlayer insulating layer 114. The polycrystalline thin film transistor TFT1 includes the first source electrode SD1 and the first drain electrode SD2 which are formed on the second interlayer insulating layer 117 and are connected to the first source area and the first drain area, respectively.

The first source electrode SD1 and the first drain electrode SD2 may be formed of a single layer or a plurality of layers formed of any one of molybdenum (Mo), aluminum (Al), chrome (Cr), gold (Au), titanium (Ti), nickel (Ni), neodymium (Nd), and copper (Cu) or an alloy thereof, but are not limited thereto.

The upper buffer layer 115 separates the second active layer ACT2 of the oxide thin film transistor TFT2 implemented by an oxide semiconductor material from the first active layer ACT1 implemented by a polycrystalline semiconductor material and provides a base for forming the second active layer ACT2.

The second gate insulating layer 116 covers the second active layer ACT2 of the oxide thin film transistor TFT2. The second gate insulating layer 116 is formed on the second active layer ACT2 implemented by the oxide semiconductor material so that the second gate insulating layer is implemented by an inorganic film. For example, the second gate insulating layer 116 may be silicon oxide (SiO₂) or silicon nitride (SiNₓ).

The second gate electrode GE2 is configured by a metal material. For example, the second gate electrode GE2 may be a single layer or a plurality of layers formed of any one of molybdenum (Mo), aluminum (Al), chrome (Cr), gold (Au), titanium (Ti), nickel (Ni), neodymium (Nd), and copper (Cu) or an alloy thereof, but is not limited thereto.

In the meantime, the oxide thin film transistor TFT2 includes a second active layer ACT2 which is formed on the upper buffer layer 115 and is implemented by an oxide semiconductor material, a second gate electrode GE2 disposed on the second gate insulating layer 116, and a second source electrode SD3 and a second drain electrode SD4. The second source electrode SD3 and the second drain electrode SD4 are disposed on the second interlayer insulating layer 117.

The second active layer ACT2 includes an intrinsic second channel area which is implemented by the oxide semiconductor material and is not doped with an impurity and a second source area and a second drain area which are doped with an impurity to become conductive.

The oxide thin film transistor TFT2 further includes a light shielding layer LS which is located below the upper buffer layer 115 and overlaps the second active layer ACT2. A light shielding layer LS blocks light incident onto the active layer ACT2 to ensure the reliability of the oxide thin film transistor TFT2. The light shielding layer LS is formed by the same material as the first gate electrode GE1 and may be formed on an upper surface of the first gate insulating layer 113. The light shielding layer LS is electrically connected to the second gate electrode GE2 to configure a dual gate.

The second source electrode SD3 and the second drain electrode SD4 are simultaneously formed of the same material as the first source electrode SD1 and the first drain electrode SD2 on the second interlayer insulating layer 117 to reduce the number of mask processes.

In the meantime, a second electrode CST2 is disposed on the first interlayer insulating layer 114 so as to overlap the first electrode CST1 to implement the storage capacitor Cst. For example, the second electrode CST2 may be a single layer or a plurality of layers formed of any one of molybdenum (Mo), aluminum (Al), chrome (Cr), gold (Au), titanium (Ti), nickel (Ni), neodymium (Nd), and copper (Cu), or an alloy thereof.

The storage capacitor Cst stores a data voltage which is applied through the data line DL for a predetermined period and then supplies the data voltage to the light emitting diode OLED. The storage capacitor Cst includes two corresponding electrodes and a dielectric material disposed therebetween. The first interlayer insulating layer 114 is located between the first electrode CST1 and the second electrode CST2.

The first electrode CST1 or the second electrode CST2 of the storage capacitor Cst may be electrically connected to the second source electrode SD3 or the second drain electrode SD4 of the oxide thin film transistor TFT2. However, it is not limited thereto and a connection relationship of the storage capacitor Cst may vary according to the pixel driving circuit.

In the meantime, a first planarization layer 118 and a second planarization layer 119 are sequentially disposed on the pixel driving circuit to planarize an upper end of the pixel driving circuit. The first planarization layer 118 and the second planarization layer 119 may be organic films, such as polyimide or acryl resin.

Further, the light emitting diode OLED is formed on the second planarization layer 119.

The light emitting diode OLED includes an anode electrode ANO, a cathode electrode CAT, and an emission layer EL disposed between the anode electrode ANO and the cathode electrode CAT. If a pixel driving circuit which commonly uses a low potential voltage connected to the cathode electrode CAT is implemented, the anode electrode ANO is disposed as a separate electrode in every sub pixel. If a pixel driving circuit which commonly uses a high potential voltage is implemented, the cathode electrode CAT may be disposed as a separate electrode in every sub pixel.

The light emitting diode OLED is electrically connected to the driving element through an intermediate electrode CNE disposed on the first planarization layer 118. Specifically, the anode electrode ANO of the light emitting diode OLED and the first source electrode SD1 of the polycrystalline thin film transistor TFT1 which configures the pixel driving circuit are connected to each other by the intermediate electrode CNE.

The anode electrode ANO is connected to the intermediate electrode CNE exposed through the contact hole which passes through the second planarization layer 119. Further, the intermediate electrode CNE is connected to the first source electrode SD1 exposed through the contact hole which passes through the first planarization layer 118.

The intermediate electrode CNE serves as a medium connecting the first source electrode SD1 and the anode electrode ANO. The intermediate electrode CNE may be formed of a conductive material, such as copper (Cu), silver (Ag), molybdenum (Mo), or titanium (Ti).

The anode electrode ANO may be formed to have a multi-layered structure including a transparent conductive film and an opaque conductive film having high reflection efficiency. The transparent conductive film is configured with a material having a relatively high work function, such as indium-tin-oxide (ITO) or indium-zinc-oxide (IZO). The opaque conductive film is configured as a single or multilayered structure including aluminum (Al), silver (Ag), copper (Cu), lead (Pb), molybdenum (Mo), titanium (Ti), or an alloy thereof. For example, the anode electrode ANO is formed with a structure in which a transparent conductive film, an opaque conductive film, and a transparent conductive film are sequentially laminated or may be formed with a structure in which a transparent conductive film and an opaque conductive film are sequentially laminated.

The emission layer EL may be formed by laminating a hole related layer, an organic emission layer, and an electron related layer on the anode electrode ANO in this order or in a reverse order.

A bank layer BNK may be a pixel definition film which exposes the anode electrode ANO of each pixel P. The bank layer BNK may be formed of an opaque material (for example, black) to suppress the light interference between adjacent pixels P. In this case, the bank layer BNK includes a light shielding material which is formed of at least any one of a color pigment, organic black, and carbon. A spacer may be further disposed on the bank layer BNK.

The cathode electrode CAT is formed on a top surface and a side surface of the emission layer EL so as to be opposite to the anode electrode ANO with the emission layer EL therebetween. The cathode electrode CAT is integrally formed on the entire active area AA. When the cathode electrode CAT is applied to a top-emission type organic light emitting display device, the cathode electrode may be configured by a transparent conductive film, such as indium-tin-oxide (ITO) or indium-zinc-oxide (IZO).

The encapsulation layer 120 may be further disposed on the cathode electrode CAT to suppress moisture permeation.

The encapsulation layer 120 blocks the permeation of moisture or oxygen from the outside into the light emitting diode OLED which is vulnerable to the moisture or oxygen from the outside. To this end, the encapsulation layer 120 may include at least one inorganic encapsulation layer and at least one organic encapsulation layer, but is not limited thereto. In the present disclosure, a structure of the encapsulation layer 120 in which a first encapsulation layer 121, a second encapsulation layer 122, and a third encapsulation layer 123 are sequentially laminated will be described as an example.

The first encapsulation layer 121 is formed on the substrate 111 on which the cathode electrode CAT is formed. The third encapsulation layer 123 is formed on the substrate 111 on which the second encapsulation layer 122 is formed and encloses a top surface, a bottom surface, and a side surface of the second encapsulation layer 122 together with the first encapsulation layer 121. The first encapsulation layer 121 and the third encapsulation layer 123 may minimize or suppress the permeation of external moisture or oxygen into the light emitting diode OLED. The first encapsulation layer 121 and the third encapsulation layer 123 may be formed of an inorganic insulating material on which low-temperature deposition is allowed, such as silicon nitride (SiNₓ), silicon oxide (SiOₓ), silicon oxynitride (SiON), or aluminum oxide (Al₂O₃). The first encapsulation layer 121 and the third encapsulation layer 123 are deposited under a low temperature atmosphere so that the damage of the light emitting diode OLED which is vulnerable to a high temperature atmosphere may be suppressed during the deposition process of the first encapsulation layer 121 and the third encapsulation layer 123.

The second encapsulation layer 122 serves as a buffer which alleviates stress between layers due to the bending of the display device 10 and planarizes the step between layers. The second encapsulation layer 122 may be formed of acryl resin, epoxy resin, phenolic resin, polyamide resin, polyimide resin, and polyethylene or a non-photosensitive organic insulating material such as silicon oxy carbon (SiOC), or a photosensitive organic insulating material such as photoacryl, on the substrate 111 on which the first encapsulation layer 121 is formed, but is not limited thereto. When the second encapsulation layer 122 is formed using an inkjet method, a dam DAM may be disposed to suppress a liquefied second encapsulation layer 122 from being diffused to an edge of the substrate 111. The dam DAM may be disposed to be closer to the edge of the substrate 111 than the second encapsulation layer 122. The dam DAM may suppress the second encapsulation layer 122 from being diffused into a pad region where a conductive pad disposed at an outermost periphery of the substrate 111 is disposed.

The dam DAM is designed to suppress the diffusion of the second encapsulation layer 122. However, when the second encapsulation layer 122 is formed to exceed a height of the dam DAM during the process, the second encapsulation layer 122 which is an organic layer may be exposed to the outside so that moisture may be easily permeated into the light emitting diode OLED. Therefore, in order to avoid the above-mentioned problem, at least ten dams DAM may be formed to overlap.

The dam DAM may be disposed on the second interlayer insulating layer 117 of the non-active area NA.

Further, the dam DAM may be simultaneously formed with the first planarization layer 118 and the second planarization layer 119. When the first planarization layer 118 is formed, a lower layer of the dam DAM is formed together and when the second planarization layer 119 is formed, an upper layer of the dam DAM is formed together so that the dam DAM may be laminated to have a double-layered structure.

Therefore, the dam DAM may be configured with the same material as the first planarization layer 118 and the second planarization layer 119, but is not limited thereto.

The dam DAM may be disposed to overlap a low potential driving power line VSS. For example, on a lower layer of a region of the non-active area NA where the dam DAM is located, the low potential driving power line VSS may be formed.

The low potential driving power line VSS and the gate driver 300 configured in a gate-in-panel (GIP) manner are formed to enclose the outer periphery of the display panel and the low potential driving power line VSS may be located at the outer periphery more than the gate driver 300. Further, the low potential driving power line VSS is connected to the cathode electrode CAT to apply a common voltage. Even though the gate driver 300 is simply illustrated in a plan view and a cross-sectional view, the gate driver 300 may be configured using a thin film transistor having the same structure as the thin film transistor of the active area AA.

The low potential driving power line VSS is disposed at the outside more than the gate driver 300. The low potential driving power line VSS is disposed at the outside more than the gate driver 300 and encloses the active area AA. For example, the low potential driving power line VSS may be formed of the same material as the first gate electrode GE1, but is not limited thereto and may be formed of the same material as the second electrode CST2 or the first source and drain electrodes SD1 and SD2, but is not limited thereto.

Further, the low potential driving power line VSS may be electrically connected to the cathode electrode CAT. The low potential driving power line VSS may supply a low potential driving voltage EVSS to the plurality of pixels P of the active area AA.

A touch layer may be disposed on the encapsulation layer 120. A touch buffer film 151 may be disposed between a touch sensor metal including touch electrode connection lines 152 and 154 and touch electrodes 155 and 156 and a cathode electrode CAT of the light emitting diode OLED.

The touch buffer film 151 may suppress the permeation of a chemical solution (a developer or an etchant) used for a manufacturing process of a touch sensor metal disposed on the touch buffer film 151 or moisture from the outside into the emission layer EL including an organic material. By doing this, the touch buffer film 151 may suppress the damage of the emission layer EL which is vulnerable to the chemical solution or the moisture.

The touch buffer film 151 may be formed of an organic insulating material which is formed at a temperature lower than a predetermined temperature (for example, 100° C.) to suppress the damage of the emission layer EL including an organic material which is vulnerable to a high temperature. The organic insulating material has a low permittivity of 1 to 3. For example, the touch buffer film 151 may be formed of an acrylic, epoxy, or siloxane based material. The touch buffer film 151 which is formed of an organic insulating material and has a planarization performance may suppress a damage of the encapsulation layer 120 caused by the bending of the organic light emitting display device and the breakage of the touch sensor metal formed on the touch buffer film 151.

According to a mutual-capacitance based touch sensor structure, the touch electrodes 155 and 156 are disposed on the touch buffer film 151 and the touch electrodes 155 and 156 may be alternately disposed.

The touch electrode connection line 152 may electrically connect the touch electrodes 155 and 156. The touch electrode connection line 152 and the touch electrodes 155 and 156 may be disposed on different layers with the touch insulating film 153 therebetween.

The touch electrode connection line 152 is disposed to overlap the bank layer BNK to suppress the degradation of the aperture ratio.

In the meantime, in the touch electrodes 155 and 156, a part of the touch electrode connection line 152 passes through an upper portion and a side surface of the encapsulation layer 120 and an upper portion and a side surface of the dam DAM to be electrically connected to a touch driving circuit (not illustrated) through the touch pad PAD.

A part of the touch electrode connection line 152 is supplied with a touch driving signal from the touch driving circuit to transmit the touch driving signal to the touch electrodes 155 and 156 and may transmit a touch sensing signal in the touch electrodes 155 and 156 to the touch driving circuit.

A touch protection film 157 may be disposed on the touch electrodes 155 and 156. In the drawing, even though it is illustrated that the touch protection film 157 is disposed only on the touch electrodes 155 and 156, it is not limited thereto. Also, the touch protection film 157 extends before and after the dam DAM to be disposed on the touch electrode connection line 152.

Further, a color filter (not illustrated) may be further disposed on the encapsulation layer 120 and the color filter may be disposed on the touch layer or located between the encapsulation layer 120 and the touch layer.

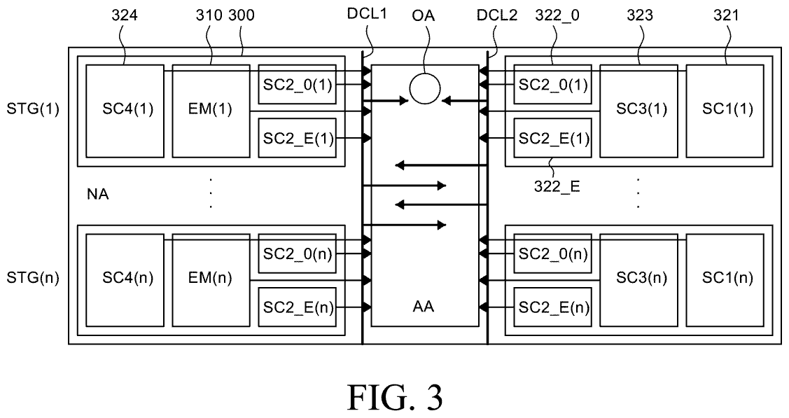

FIG. 3 is a view of a configuration of a gate driver in a display device according to an example embodiment of the present disclosure.

Referring to FIG. 3, the gate driver 300 is configured by an emission control signal driver 310 and a scan driver 320. The scan driver 320 is configured by first to fourth scan drivers 321, 322, 333, and 334. Further, the second scan driver 322 may be configured by an odd-numbered second scan driver 322_O and an even-numbered second scan driver 322_E.

In the gate driver 300, shift registers may be symmetrically disposed on both sides of the active area AA. Further, in the gate driver 300, a shift register at one side of the active area AA includes second scan drivers 322_O and 322_E, a fourth scan driver 324, and an emission control signal driver 310, respectively. A shift register at the other side of the active area AA may include a first scan driver 321, second scan drivers 322_O and 322_E, and a third scan driver 323, respectively. However, the present disclosure is not limited thereto and the emission control signal driver 310 and the first to fourth scan drivers 321, 322, 323, and 324 may be disposed in different ways according to the example embodiments.

Each of stages STG1 to STGn of the shift register may include first scan signal generators SC1(1) to SC1(n), second signal generators SC2_O(1) to SC2_O(n), SC2_E(1) to SC2_E(n), third scan signal generators SC3(1) to SC3(n), fourth scan signal generators SC4(1) to SC4(n), and emission control signal generators EM(1) to EM(n), respectively.

The first scan signal generators SC1(1) to SC1(n) output first scan signals SC1(1) to SC1(n) through first gate lines SCL1 of the display panel 100. The second scan signal generators SC2(1) to SC2(n) output second scan signals SC2(1) to SC2(n) through second gate lines SCL2 of the display panel 100. The third scan signal generators SC3(1) to SC3(n) output third scan signals SC3(1) to SC3(n) through third gate lines SCL3 of the display panel 100. The fourth scan signal generators SC4(1) to SC4(n) output fourth scan signals SC4(1) to SC4(n) through fourth gate lines SCL4 of the display panel 100. The emission control signal generators EM(1) to EM(n) output emission control signals EM(1) to EM(n) through emission control lines EML of the display panel 100.

The first scan signals SC1(1) to SC1(n) may be used as signals to drive an A-th transistor (for example, a compensation transistor) included in the pixel circuit. The second scan signals SC2(1) to SC2(n) may be used as signals to drive a B-th transistor (for example, a data supply transistor) included in the pixel circuit. The third scan signals SC3(1) to SC3(n) may be used as signals to drive a C-th transistor (for example, a bias transistor) included in the pixel circuit. The fourth scan signals SC4(1) to SC4(n) are used as signals to drive a D-th transistor (for example, an initialization transistor) included in the pixel circuit. The emission control signals EM(1) to EM(n) may be used as signals to drive an E-th transistor (for example, an emission control transistor) included in the pixel circuit. For example, when the emission control transistors of pixels are controlled using emission control signals EM(1) to EM(n), an emission time of the light emitting diode is variable.

Referring to FIG. 3, in the active area AA, one or more optical areas OA may be disposed.

One or more optical areas OA may be disposed so as to overlap one or more sensor modules, such as an image capturing device such as a camera (image sensor) and a sensing sensor such as a proximity sensor and an illuminance sensor. For example, the optical area OA may be disposed so as to overlap an infrared sensing sensor.

In one or more optical areas OA, a light transmissive structure is formed to have a predetermined level or higher of transmittance for an operation of an optical electronic device. In other words, the number of pixels P per unit area in one or more optical areas OA may be smaller than the number of pixels P per unit area in a normal area excluding the optical areas OA, in the active area AA. That is, a resolution of one or more optical areas OA may be lower than a resolution of a normal area in the active area AA.

A light transmissive structure in one or more optical areas OA may be configured by patterning the cathode electrode in a part in which the pixel P is not disposed. At this time, the cathode electrode to be patterned may be removed using laser or the cathode electrode is selectively formed to be patterned using a material such as a cathode deposition stop layer.

In summary, one or more optical areas OA may include a pixel area in which the plurality of pixels P is disposed and a transmissive area in which a light transmissive structure through which light of one or more sensor modules passes is disposed.

In the meantime, in one or more optical areas OA, the optical transmissive structure may be configured by separately forming the light emitting diode OLED and the pixel circuit in the pixel P. In other words, the light emitting diode OLED of the pixel P is located on the optical areas OA and the plurality of transistors TFT which configures the pixel circuit is disposed in the vicinity of the optical areas OA. Therefore, the light emitting diode OLED and the pixel circuit may be electrically connected by means of a transparent metal layer.

Further, referring to FIGS. 1 to 4, a plurality of constant power lines DCL1 and DCL2 configured to apply a constant power to the plurality of pixels P may be disposed on both sides of the display panel 100.

Further, the plurality of constant power lines DCL1 and DCL2 is connected to a power line VL included in the plurality of pixels to apply a bias voltage Vobs, a reset voltage Var, and an initialization voltage Vini which are constant powers to the plurality of pixels P.

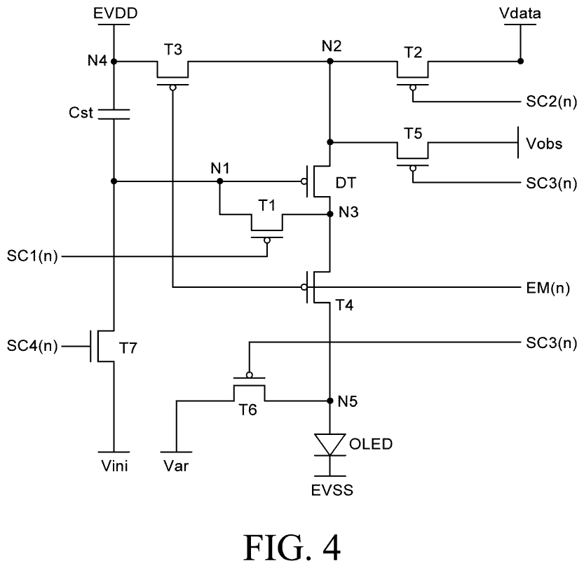

FIG. 4 is a view for a pixel circuit in a display device according to an example embodiment of the present disclosure.

FIG. 4 illustrates an example of the pixel circuit and it is not specifically limited as long as the structure may control the emission of the light emitting diode OLED by applying an EM signal EM(n). For example, the pixel circuit may include an additional scan signal, a switching thin film transistor connected thereto, and a switching thin film transistor to which an additional initialization voltage is applied. Further, a connection relationship of a switching element and a connection location of a capacitor may be disposed in various manners. Hereinafter, for the convenience of description, a display device with a pixel circuit structure of FIG. 4 will be described.

Referring to FIG. 4, each of the plurality of pixels P may include a pixel circuit having a driving transistor DT and a light emitting diode OLED connected to the pixel circuit.

The pixel circuit controls the driving current which flows in the light emitting diode OLED to drive the light emitting diode OLED. The pixel circuit may include the driving transistor DT, first to seventh transistors T1 to T7, and the storage capacitor Cst. Each of the transistors DT, T1 to T7 may include a first electrode, a second electrode, and a gate electrode. One of the first electrode and the second electrode is a source electrode and the other one of the first electrode and the second electrode may be a drain electrode.

Each of the transistors DT, T1 to T7 may be a P-type thin film transistor or an N-type thin film transistor. In the example embodiment of FIG. 3, the first transistor T1 and the seventh transistor T7 are N-type thin film transistors and the remaining transistors DT, T2 to T6 are P-type thin film transistors. However, it is not limited thereto and depending on the example embodiment, all or some of the transistors DT, T1 to T7 may be P-type thin film transistors or N-type thin film transistors. Further, the N-type thin film transistor may be an oxide thin film transistor and the P-type thin film transistor may be a polycrystalline silicon thin film transistor.

Hereinafter, it is exemplified that the first transistor T1 and the seventh transistor T7 are N-type thin film transistors and the remaining transistors DT, T2 to T6 are P-type thin film transistors. Accordingly, a high voltage is applied to the first transistor T1 and the seventh transistor T7 to be turned on and a low voltage is applied to the remaining transistors DT, T2 to T6 to be turned on.

According to the example embodiment, the first transistor T1 which configures the pixel circuit serves as a compensation transistor, the second transistor T2 serves as a data supplying transistor, the third and fourth transistors T3 and T4 serve as emission control transistors, and the fifth transistor T5 serves as a bias transistor. Further, the sixth transistor T6 serves as a reset transistor and the seventh transistor T7 serves as an initialization transistor.

The light emitting diode OLED may include an anode electrode and a cathode electrode. The anode electrode of the light emitting diode OLED is connected to a fifth node N5 and the cathode electrode may be connected to a low potential driving voltage EVSS.

The driving transistor DT may include a first electrode connected to a second node N2, a second electrode connected to a third node N3, and a gate electrode connected to a first node N1. The driving transistor DT may provide a driving current Id to the light emitting diode OLED based on a voltage of the first node N1 (or a data voltage stored in the storage capacitor Cst to be described below).

The first transistor T1 may include a first electrode connected to the first node N1, a second electrode connected to the third node N3, and a gate electrode which receives a first scan signal SC1(n). The first transistor T1 is turned on in response to the first scan signal SC1(n) and is diode-connected between the first node N1 and the third node N3 to sample a threshold voltage Vth of the driving transistor DT. Such a first transistor T1 may be a compensation transistor.

The storage capacitor Cst may be connected or formed between the first node N1 and a fourth node N4. The storage capacitor Cst may store or maintain the supplied high potential driving voltage EVDD.

The second transistor T2 may include a first electrode which is connected to a data line DL (or receives a data voltage Vdata), a second electrode connected to the second node N2, and a gate electrode which receives a second scan signal SC2(n). The second transistor T2 is turned on in response to a second scan signal SC2(n) and may transmit the data voltage Vdata to the second node N2. Such a second transistor T2 may be a data supply transistor.

The third transistor T3 and the fourth transistor T4 (or first and second emission control transistors) are connected between the high potential driving voltage EVDD and the light emitting diodes OLED and form a current movement path through which the driving current Id generated by the driving transistor DT moves.

The third transistor T3 may include a first electrode which is connected to the fourth node N4 to receive a high potential driving voltage EVDD, a second electrode connected to the second node N2, and a gate electrode which receives an emission control signal EM(n).

The fourth transistor T4 may include a first electrode connected to the third node N3, a second electrode connected to the fifth node N5 (or the anode electrode of the light emitting diode OLED), and a gate electrode which receives the emission control signal EM(n).

The third and fourth transistors T3 and T4 are turned on in response to the emission control signal EM(n) and in this case, the driving current Id is supplied to the light emitting diode OLED and the light emitting diode OLED may emit light with a luminance corresponding to the driving current Id.

The fifth transistor T5 may include a first electrode which receives a bias voltage Vobs, a second electrode connected to the second node N2, and a gate electrode which receives a third scan signal SC3(n). Such a fifth transistor T5 may be a bias transistor.

The sixth transistor T6 may include a first electrode which receives a reset voltage Var, a second electrode connected to the fifth node N5, and a gate electrode which receives the third scan signal SC3(n).

The sixth transistor T6 is turned on in response to the third scan signal SC3(n), before the light emitting diode OLED emits light (or after the light emitting diode OLED emits light) and may reset the anode electrode (or the pixel electrode) of the light emitting diode OLED using the reset voltage Var. The light emitting diode OLED may have a parasitic capacitor formed between the anode electrode and the cathode electrode. Further, the parasitic capacitor is charged while the light emitting diode OLED emits light so that the anode electrode of the light emitting diode EL may have a specific voltage. Accordingly, the reset voltage Var is applied to the anode electrode of the light emitting diode OLED through the sixth transistor T6 to reset a quantity of charges accumulated in the light emitting diode OLED.

In the present disclosure, the gate electrodes of the fifth and sixth transistors T5 and T6 are configured to commonly receive the third scan signal SC3(n). However, the present disclosure is not essentially limited thereto and the gate electrodes of the fifth and sixth transistors T5 and T6 are configured to receive separate scan signals to independently controlled.

The seventh transistor T7 may include a first electrode which receives an initialization voltage Vini, a second electrode connected to the first node N1, and a gate electrode which receives a fourth scan signal SC4(n).

The seventh transistor T7 is turned on in response to the fourth scan signal SC4(n) and may initialize the gate electrode of the driving transistor DT using the initialization voltage Vini. In the gate electrode of the driving transistor DT, unnecessary charges may remain due to the high potential driving voltage EVDD stored in the storage capacitor Cst. Accordingly, the initialization voltage Vini is applied to the gate electrode of the driving transistor DT through the seventh transistor T7 to initialize the remaining quantity of charges.

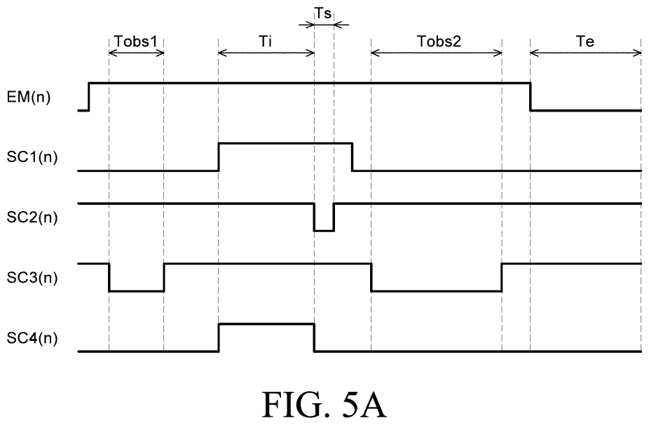

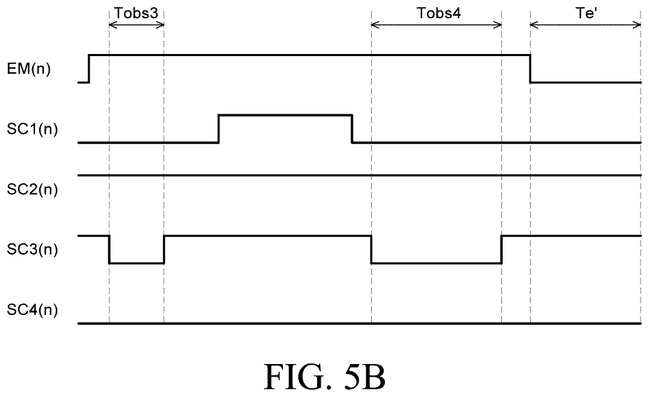

FIGS. 5A and 5B are views for explaining an operation of a scan signal and an emission control signal in a refresh period and a hold period in a pixel circuit illustrated in FIG. 4.

A display device according to the example embodiment of the present disclosure may operate as a variable refresh rate (VRR) mode display device. In the VRR mode, the pixel is driven at a constant frequency and at the time when a high speed driving is necessary, a refresh rate at which the data voltage Vdata is updated is increased to operate the pixel or at a time when the power consumption needs to be lowered or low-speed driving is necessary, the refresh rate is lowered to operate the pixel.

Each of the plurality of pixels P may be driven by a combination of a refresh frame and a hold frame in one second. In the present disclosure, one set is defined that a combination of a refresh period in which the data voltage Vdata is updated and a hold period in which the data voltage Vdata is not updated is repeated for one second. Further, one set period is a period in which a combination of the refresh period and the hold period is repeated.

When the refresh rate is driven at 120 Hz, it is driven only with the refresh period. That is, the refresh period is driven 120 times in one second. One refresh period is 1/120=8.33 ms and one set period is also 8.33 ms.

When the refresh rate is driven at 60 Hz, the refresh period and the hold period are alternately driven. That is, the refresh period and the hold period may be alternately driven 60 times each in one second. One refresh period and one hold period are 0.5/60=8.33 ms and one set period is 16.66 ms.

When the refresh rate is driven at 1 Hz, one frame may be driven with one refresh period and 119 hold periods after the one refresh period. Further, when the refresh rate is driven at 1 Hz, one frame may be driven with a plurality of refresh periods and a plurality of hold periods. At this time, one refresh period and one hold period are 1/120=8.33 ms and one set period is 1 s.

In the refresh period, a new data voltage Vdata is charged to apply a new data voltage Vdata to the driving transistor DT and in the hold period, a data voltage Vdata of a previous frame is held to be used as it is. In the meantime, in the hold period, a process of applying the new data voltage Vdata to the driving transistor DT is omitted so that the hold period is also referred to as a skip period.

Each of the plurality of pixels P may initialize a voltage which is charged in the pixel circuit or remains during the refresh period. Specifically, each of the plurality of pixels P may remove the influence of the data voltage Vdata and the high potential driving voltage EVDD stored in the previous frame in the refresh period. Accordingly, each of the plurality of pixels P may display an image corresponding to a new data voltage Vdata in the hold period.

Each of the plurality of pixels P supplies a driving current corresponding to the data voltage Vdata to the light emitting diode OLED to display images and may maintain a turned-on state of the light emitting diode OLED, during the hold period.

First, the driving of the pixel circuit and the light emitting diode in the refresh period of FIG. 5A will be described. The refresh period may include at least one bias period Tobs1 and Tobs2, an initialization period Ti, a sampling period Ts, and an emission period Te, but this is just an example embodiment and is not necessarily bound to this order.

Referring to FIG. 5A, the pixel circuit may operate including at least one bias periods Tobs1 and Tobs2 during the refresh period.

At least one bias period Tobs1 and Tobs2 is a period in which an on-bias stress operation OBS to apply a bias voltage Vobs is performed, the emission control signal EM(n) is a high voltage, and the third and fourth transistors T3 and T4 operate to be off. The first scan signal SC1(n) and the fourth scan signal SC4(n) are low voltages and the first transistor T1 and the seventh transistor T7 operate to be off. The second scan signal SC2 is a high voltage and the second transistor T2 operates to be off.

The third scan signal SC3(n) is input as a low voltage and the fifth and sixth transistors T5 and T6 are turned on. As the fifth transistor T5 is turned on, the bias voltage Vobs is applied to the first electrode of the driving transistor DT connected to the second node N2.

Here, the bias voltage Vobs is applied to the third node N3 which is a drain electrode of the driving transistor DT so that a charging time or charging delay of the voltage of the fifth node N5 which is the anode electrode of the light emitting diode OLED in the emission period is reduced. The driving transistor DT maintains a stronger saturation state.

For example, the higher the bias voltage Vobs, the higher the voltage of the third node N3 which is the drain electrode of the driving transistor DT and the lower the gate-source voltage or the drain-source voltage of the driving transistor DT. Accordingly, the bias voltage Vobs is desirably higher than the data voltage Vdata.

At this time, the magnitude of the drain-source current Id which passes through the driving transistor DT may be reduced and in a positive bias stress situation, the stress of the driving transistor DT is reduced to solve the charging delay of the voltage of the third node N3. In other words, before sampling a threshold voltage Vth of the driving transistor DT, the on-bias stress operation OBS is performed to relieve the hysteresis of the driving transistor DT.

Accordingly, in at least one bias period Tobs1 and Tobs2, the on-bias stress operation OBS may be defined as an operation of directly applying an appropriate bias voltage to the driving transistor DT during non-emission periods.

Further, in at least one bias period Tobs1 and Tobs2, the sixth transistor T6 is turned on so that the anode electrode (or the pixel electrode) of the light emitting diode OLED connected to the fifth node N5 is reset with the reset voltage Var.

However, the gate electrodes of the fifth and sixth transistors T5 and T6 are configured to receive separate scan signals to be independently controlled. That is, it is not required to necessarily simultaneously apply the bias voltage to the first electrode of the driving transistor DT and the anode electrode of the light emitting diode OLED in the bias period.

Referring to FIG. 5A, the pixel circuit may operate including the initialization period Ti during the refresh period. The initialization period Ti is a period in which the voltage of the gate electrode of the driving transistor DT is initialized.

The first scan signal SC1(n) to the fourth scan signal SC4(n) and the emission control signal EM(n) are high voltages and the first transistor T1 and the seventh transistor T7 operate to be turned on. The second to sixth transistors T2, T3, T4, T5, and T6 operate to be turned off. As the first and seventh transistors T1 and T7 operate to be turned on, the gate electrode of the driving transistor DT and the second electrode connected to the first node N1 are initialized with the initialization voltage Vini.

Referring to FIG. 5A, the pixel circuit may operate including the sampling period Ts during the refresh period. The sampling period is a period in which the threshold voltage Vth of the driving transistor DT is sampled.

The first scan signal SC1(n), the third scan signal SC3(n), and the emission control signal EM(n) are high voltages and the second scan signal SC2(n) and the fourth scan signal SC4(n) are low voltages. Accordingly, the third to seventh transistors T3, T4, T5, T6, and T7 operate to be turned off, the first transistor T1 maintains an on-state, and the second transistor T2 operates to be turned on. That is, the second transistor T2 is turned on to apply the data voltage Vdata to the driving transistor DT and the first transistor T1 is diode-connected between the first node N1 and the third node N3 to sample the threshold voltage Vth of the driving transistor DT.

Referring to FIG. 5A, the pixel circuit may operate including an emission period Te during the refresh period. The emission period Te is a period in which the sampled threshold voltage Vth is cancelled and the driving current corresponding to the sampled data voltage allows the light emitting diode OLED to emit light.

The emission control signal EM(n) is a low voltage and the third and fourth transistors T3 and T4 operate to be turned on.

As the third transistor T3 operates to be turned on, the high potential driving voltage EVDD connected to the fourth node N4 is applied to the first electrode of the driving transistor DT connected to the second node N2 through the third transistor T3. The driving current Id which is supplied from the driving transistor DT to the light emitting diode OLED via the fourth transistor T4 becomes independent of the value of the threshold voltage Vth of the driving transistor DT so that the threshold voltage Vth of the driving transistor DT is compensated for operation.

Next, the driving of the pixel circuit and the light emitting diode during the hold period will be described with reference to FIG. 5B.

The hold period may include at least one bias period Tobs3 and Tobs4 and an emission period Te′. Description of an operation of the pixel circuit which is the same as the operation of the refresh period will be omitted.

As described above, in the refresh period, a new data voltage Vdata is charged to apply a new data voltage Vdata to the gate electrode of the driving transistor DT, but in the hold period, the data voltage Vdata of the refresh period is held to be used as it is. Accordingly, the hold period does not require the initialization period T1 and the sampling period Ts, unlike the refresh period.

In the operation of the hold period, a single on-bias stress operation OBS is sufficient. However, in the example embodiment, for the convenience of the driving circuit, the third scan signal SC3(n) of the hold period is driven as the same as the third scan signal SC3(n) of the refresh period so that the on-bias stress operation OBS may operate twice as in the refresh period.

The difference between the driving signal in the refresh period which has been described with reference to FIG. 5A and the driving signal of the hold period in FIG. 5B is the second and fourth scan signals SC2(n) and SC4(n). In the hold period, the initialization period Ti and the sampling period Ts are not necessary so that unlike the refresh period, the second scan signal SC2(n) is always a high voltage and the fourth scan signal SC4(n) is always a low voltage. That is, the second and seventh transistors T2 and T7 operate to be always off.

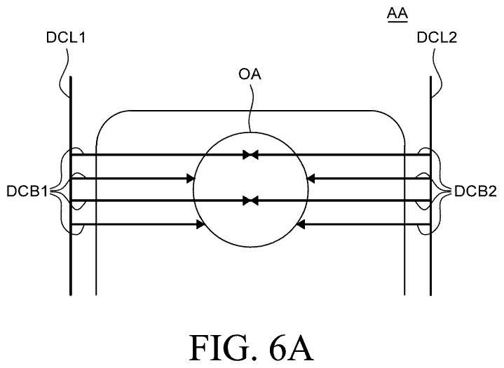

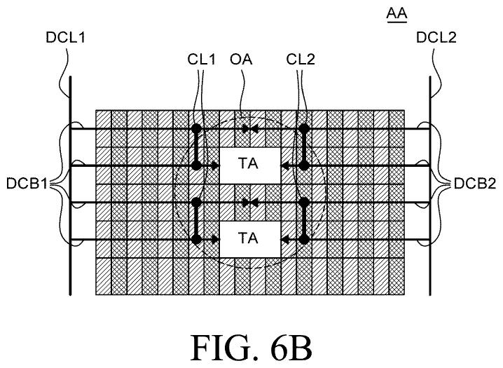

FIGS. 6A and 6B are views for explaining a placement relationship of a plurality of constant power lines when an optical area of a display device according to an example embodiment of the present disclosure is disposed in the center.

Specifically, FIG. 6A illustrates only the placement relationship of an optical area of a display device according to an example embodiment of the present disclosure and a plurality of constant power lines. Further, FIG. 6B illustrates only the placement relationship of a transmissive area in an optical area of a display device according to an example embodiment of the present disclosure and a plurality of constant power lines. In FIG. 6B, the hatched area denotes a plurality of pixel areas.

Referring to FIG. 6A, the optical area OA may be disposed in the center of the active area AA.

Further, the plurality of constant power lines may include a plurality of main lines DCL1 and DCL2 disposed at the outside of the active area AA and a plurality of sub lines DCB1 and DCB2 extending into the active area AA.

Specifically, the plurality of main lines DCL1 and DCL2 may include a first main line DCL1 disposed at one side of the active area AA and a second main line disposed at the other side of the active area AA. Further, each of the first main line DCL1 and the second main line DCL2 extends in one direction.

Further, the plurality of sub lines DCB1 and DCB2 is branched from at least one of the plurality of main lines DCL1 and DCL2 to be connected to the plurality of pixels.

Specifically, the plurality of sub lines DCB1 and DCB2 may include a plurality of first sub lines DCB1 branched from the first main line DCL1 and a plurality of second sub lines DCB2 branched from the second main line DCL2.

To be more specific, the plurality of first sub lines DCB1 may extend from one side of the active area AA to the optical area OA and the plurality of second sub lines DCB2 may extend from the other side of the active area AA to the optical area OA.

Further, the optical area OA is disposed in the center of the active area AA so that a length of the plurality of first sub lines DCB1 may be equal to a length of the plurality of second sub lines DCB2.

Further referring to FIG. 6B, some of the plurality of first sub lines DCB1 may extend to a transmissive area TA, but the others of the plurality of first sub lines DCB1 may not extend to the transmissive area TA.

Further, some of the plurality of second sub lines DCB2 may extend to a transmissive area TA, but the others of the plurality of second sub lines DCB2 may not extend to the transmissive area TA.

For example, a first first sub line DCB1 and a third first sub line DCB1 and a first second sub line DCB2 and a third second sub line DCB2 from the top do not extend to the transmissive area. However, a second first sub line DCB1 and a fourth first sub line DCB1 and a second second sub line DCB2 and a fourth second sub line DCB2 from the top may extend to the transmissive area TA.

Further, the plurality of first sub lines DCB1 and the plurality of second sub lines DCB2 which do not extend to the transmissive area TA may be in contact with each other.

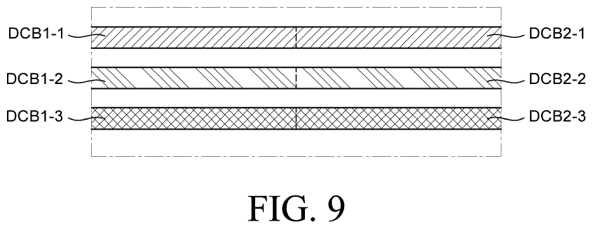

Specifically, the first first sub line DCB1 and the first second sub line DCB2 from the top are connected to each other and the third first sub line DCB1 and the third second sub line DCB2 from the top are connected to each other. A specific connection relationship thereof will be described with reference to FIG. 9.

In the meantime, among the plurality of constant power lines, adjacent constant power lines may be connected to each other.

Specifically, the adjacent first sub lines DCB1 may be connected by the first connection line CL1. For example, the first first sub line DCB1 and the second first sub line DCB1 from the top may be connected by the first connection line CL1. Further, the third first sub line DCB1 and the fourth first sub line DCB1 from the top may be connected by the first connection line CL1.

Further, the adjacent second sub lines DCB2 may be connected by the second connection line CL2. For example, the first second sub line DCB2 and the second second sub line DCB2 from the top may be connected by the second connection line CL2. Further, the third second sub line DCB2 and the fourth second sub line DCB2 from the top may be connected by the second connection line CL2.

Hereinafter, a change in the placement relationship of the constant power lines due to the change of the position of the optical area OA will be described. A redundant description of the constant power line which has been already described will be omitted.

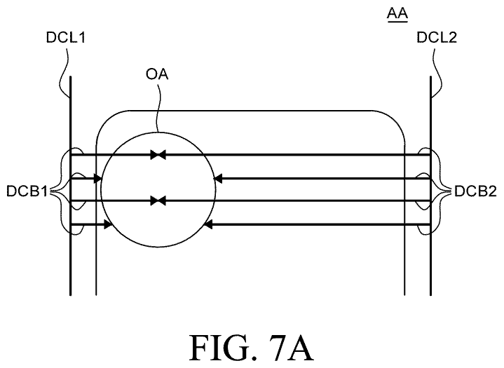

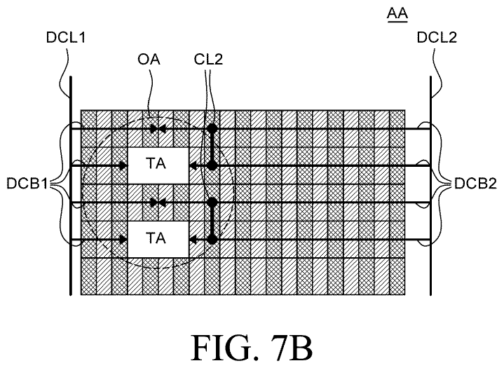

FIGS. 7A and 7B are views for explaining a placement relationship of a plurality of constant power lines when an optical area of a display device according to an example embodiment of the present disclosure is disposed at one side.

Specifically, FIG. 7A illustrates only the placement relationship of an optical area and a plurality of constant power lines of a display device according to an example embodiment of the present disclosure. Further, FIG. 7B illustrates only the placement relationship of a transmissive area in an optical area and a plurality of constant power lines of a display device according to an example embodiment of the present disclosure. Further, in FIG. 7B, the hatched area denotes a plurality of pixel areas.

Referring to FIG. 7A, the optical area OA may be disposed at one side of the active area AA.

Therefore, the length of the plurality of first sub lines DCB1 may be shorter than a length of the plurality of second sub lines DCB2.

Further referring to FIG. 7B, some of the plurality of first sub lines DCB1 may extend to a transmissive area TA, but the others of the plurality of first sub lines DCB1 may not extend to the transmissive area TA.

Further, some of the plurality of second sub lines DCB2 may extend to a transmissive area TA, but the others of the plurality of second sub lines DCB2 may not extend to the transmissive area TA.

For example, a first first sub line DCB1 and a third first sub line DCB1 and a first second sub line DCB2 and a third second sub line DCB2 from the top do not extend to the transmissive area. However, a second first sub line DCB1 and a fourth first sub line DCB1 and a second second sub line DCB2 and a fourth second sub line DCB2 from the top may extend to the transmissive area TA.

In the meantime, among the plurality of second sub lines DCB2 having a longer length, adjacent second sub lines DCB2 may be connected to each other and the plurality of first sub lines DCB1 having a shorter length may be separated from each other.

For example, the first second sub line DCB2 and the second second sub line DCB2 from the top may be connected by the second connection line CL2. Further, the third second sub line DCB2 and the fourth second sub line DCB2 from the top may be connected by the second connection line CL2.

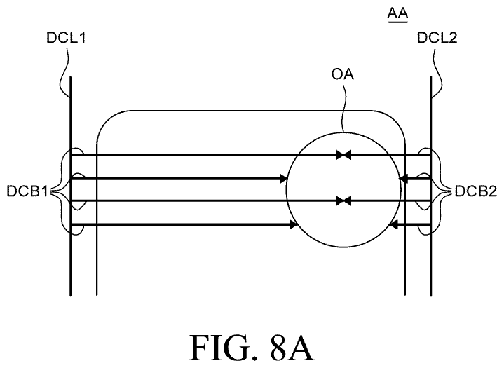

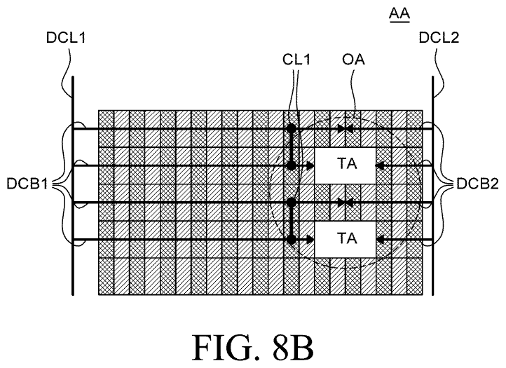

FIGS. 8A and 8B are views for explaining a placement relationship of a plurality of constant power lines when an optical area of a display device according to an example embodiment of the present disclosure is disposed at the other side.

Specifically, FIG. 8A illustrates only the placement relationship of an optical area and a plurality of constant power lines of a display device according to an example embodiment of the present disclosure. Further, FIG. 8B illustrates only the placement relationship of a transmissive area in an optical area and a plurality of constant power lines of a display device according to an example embodiment of the present disclosure. Further, in FIG. 8B, the hatched area denotes a plurality of pixel areas.

Referring to FIG. 8A, the optical area OA may be disposed at the other side of the active area AA.

Therefore, the length of the plurality of first sub lines DCB1 may be longer than a length of the plurality of second sub lines DCB2.

Further referring to FIG. 8B, some of the plurality of first sub lines DCB1 may extend to a transmissive area TA, but the others of the plurality of first sub lines DCB1 may not extend to the transmissive area TA.

Further, some of the plurality of second sub lines DCB2 may extend to a transmissive area TA, but the others of the plurality of second sub lines DCB2 may not extend to the transmissive area TA.

For example, a first first sub line DCB1 and a third first sub line DCB1 and a first second sub line DCB2 and a third second sub line DCB2 from the top do not extend to the transmissive area. However, a second first sub line DCB1 and a fourth first sub line DCB1 and a second second sub line DCB2 and a fourth second sub line DCB2 from the top may extend to the transmissive area TA.

In the meantime, among the plurality of first sub lines DCB1 having a longer length, adjacent first sub lines DCB1 are connected to each other and the plurality of second sub lines DCB2 having a shorter length may be separated from each other.

For example, the first first sub line DCB1 and the second first sub line DCB1 from the top may be connected by the first connection line CL1. Further, the third first sub line DCB1 and the fourth first sub line DCB1 from the top may be connected by the first connection line CL1.

FIG. 9 is a view for explaining a connection relationship of a plurality of sub lines of a display device according to an example embodiment of the present disclosure.

As illustrated in FIG. 9, a plurality of first sub lines may be divided into a plurality of 1-1-th sub lines DCB1-1, a plurality of 1-2-th sub lines DCB1-2, and a plurality of 1-3-th sub lines DCB1-3 according to an applied voltage.

A reset voltage Var may be applied to the plurality of 1-1-th sub lines DCB1-1, an initialization voltage Vini may be applied to the plurality of 1-2-th sub lines DCB1-2, and a bias voltage Vobs may be applied to the plurality of 1-3-th sub lines DCB1-3.

A plurality of second sub lines may be divided into a plurality of 2-1-th sub lines DCB2-1, a plurality of 2-2-th sub lines DCB2-2, and a plurality of 2-3-th sub lines DCB2-3 according to an applied voltage.

A reset voltage Var may be applied to the plurality of 2-1-th sub lines DCB2-1, an initialization voltage Vini may be applied to the plurality of 2-2-th sub lines DCB2-2, and a bias voltage Vobs may be applied to the plurality of 2-3-th sub lines DCB2-3.

Further, as illustrated in FIGS. 6B, 7B, and 8B, the first sub line DCB1 and the second sub line DCB2 which do not extend to the transmissive area TA are disposed on the same layer and may be in contact with each other.

Specifically, the 1-1-th sub line DCB1-1 and the 2-1-th sub line DCB2-1 which do not extend to the transmissive area TA may be in contact with each other on a first layer. The 1-2-th sub line DCB1-2 and the 2-2-th sub line DCB2-2 which do not extend to the transmissive area TA may be in contact with each other on a second layer and the 1-3-th sub line DCB1-3 and the 2-3-th sub line DCB2-3 which do not extend to the transmissive area TA may be in contact with each other on a third layer.

The first layer may be any one layer of a layer on which gate electrodes GE1 and GE2 of transistors are formed, a layer on which source electrodes and drain electrodes SD1, SD2, SD3, and SD4 of transistors are formed, a layer on which an intermediate electrode CNE is formed, and a layer on which an anode electrode ANO is formed.

Further, the second layer may be the other one layer of the layer on which gate electrodes GE1 and GE2 of transistors are formed, the layer on which source electrodes and drain electrodes SD1, SD2, SD3, and SD4 of transistors are formed, the layer on which an intermediate electrode CNE is formed, and the layer on which an anode electrode ANO is formed.

Further, the third layer may be still the other one layer of the layer on which gate electrodes GE1 and GE2 of transistors are formed, the layer on which source electrodes and drain electrodes SD1, SD2, SD3, and SD4 of transistors are formed, the layer on which an intermediate electrode CNE is formed, and the layer on which an anode electrode ANO is formed.

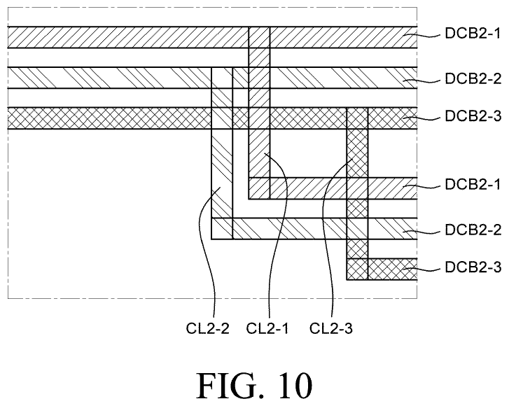

FIG. 10 is a view for explaining a placement relationship of a plurality of sub lines and a connection line of a display device according to an example embodiment of the present disclosure.

Specifically, FIG. 10 illustrates that a plurality of second sub lines and second connection lines are disposed on the same layer.

As illustrated in FIG. 10, adjacent sub lines and connection lines may be disposed on the same layer.

Further, the second connection line may include a 2-1-th connection line CL2-1, a 2-2-th connection line CL2-2, and a 2-3-th connection line CL2-3 which are disposed on different layers.

Adjacent 2-1-th sub lines DCB2-1 may be connected by the 2-1-th connection line CL2-1 and all the adjacent 2-1-th sub lines DCB2-1 and the 2-1-th connection line CL2-1 may be disposed on the first layer.

Further, adjacent 2-2-th sub lines DCB2-2 may be connected by the 2-2-th connection line CL2-2 and all the adjacent 2-2-th sub lines DCB2-2 and the 2-2-th connection line CL2-2 may be disposed on the second layer.

Further, adjacent 2-3-th sub lines DCB2-3 may be connected by the 2-3-th connection line CL2-3 and all the adjacent 2-3-th sub lines DCB2-3 and the 2-3-th connection line CL2-3 may be disposed on the third layer.

In the display device according to the example embodiment of the present disclosure, constant power lines disposed in the optical area are connected to each other to minimize resistance of the constant power lines. Therefore, in the display device according to the example embodiment of the present disclosure, voltage drop of a bias voltage, a reset voltage, or an initialization voltage which is a constant power applied by the constant power line may be minimized. Accordingly, a bias voltage, a reset voltage, or an initialization voltage which is a uniform constant power may be applied to a plurality of pixels disposed in an optical area to ensure a luminance uniformity of the optical area.

Specifically, when the optical area is disposed to be leaned to one side of the active area, a deviation in bias voltage, a reset voltage, or an initialization voltage which is a constant power applied to the plurality of pixels disposed in the optical area may be caused due to a deviation in the length between the constant power lines disposed on both sides of the active area.

Therefore, as described with reference to FIGS. 7A to 8B, in the display device according to the example embodiment of the present disclosure, sub lines having a longer length are connected to each other to minimize a resistance deviation of the constant power lines disposed at both sides of the optical area. Accordingly, a bias voltage, a reset voltage, or an initialization voltage which is a uniform constant power may be applied to a plurality of pixels disposed at both sides of the optical area to ensure a luminance uniformity of the optical area.

Further, in the display device according to the example embodiment of the present disclosure, a connection line which connects sub lines having a longer length may be disposed in the pixel area, rather than the transmissive area of the optical area. Therefore, the display device according to the example embodiment of the present disclosure also has an advantage in that sub lines having a longer length are connected to each other without degrading the transmittance.

Hereinafter, a display device according to another example embodiment of the present disclosure will be described. The only difference between the example embodiment of the present disclosure and another example embodiment is an interlayer relationship of the plurality of constant power lines so that the difference will be mainly described below and a redundant description will be omitted.

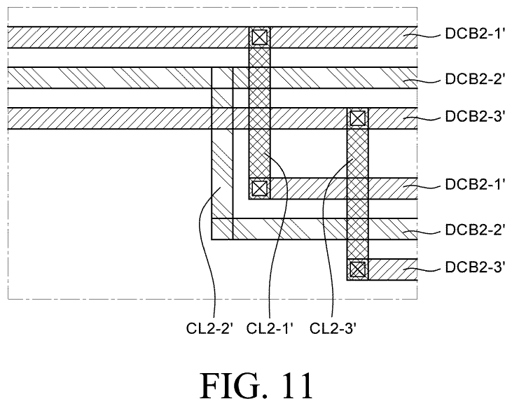

FIG. 11 is a view for explaining a placement relationship of a plurality of sub lines and a connection line of a display device according to another example embodiment of the present disclosure.

Specifically, as illustrated in FIG. 11, a plurality of second sub lines may be connected by a connection line disposed on a different layer.

In the display device according to another example embodiment of the present disclosure, a plurality of 2-1-th sub lines DCB2-1′ and a plurality of 2-3-th sub lines DCB2-3′ may be disposed on a first layer and a plurality of 2-2-th sub lines DCB2-2′ may be formed on a second layer.

Further, the plurality of 2-1-th sub lines DCB2-1′ and the plurality of 2-3-th sub lines DCB2-3′ disposed on the first layer may have a first linear resistance and the plurality of 2-2-th sub lines DCB2-2′ disposed on the second layer may have a second linear resistance. The first linear resistance may be lower than the second linear resistance.

Further, the plurality of 2-1-th sub lines DCB2-1′ having a first linear resistance which is a lower linear resistance may be connected to a 2-1-th connection line CL2-1′ disposed on the third layer through a contact hole. The plurality of 2-3-th sub lines DCB2-3′ having a first linear resistance which is a lower linear resistance may be connected to a 2-3-th connection line CL2-3′ disposed on the third layer through a contact hole.

Further, the plurality of 2-2-th sub lines DCB2-2′ having a second linear resistance which is a higher linear resistance may be connected to a 2-2-th connection line CL2-2′ disposed on the same second layer without passing through the contact hole.

As described above, the first layer may be any one layer of a layer on which gate electrodes GE1 and GE2 of transistors are formed, a layer on which source electrodes and drain electrodes SD1, SD2, SD3, and SD4 of transistors are formed, a layer on which an intermediate electrode CNE is formed, and a layer on which an anode electrode ANO is formed.

Further, the second layer may be the other one layer of the layer on which gate electrodes GE1 and GE2 of transistors are formed, the layer on which source electrodes and drain electrodes SD1, SD2, SD3, and SD4 of transistors are formed, the layer on which an intermediate electrode CNE is formed, and the layer on which an anode electrode ANO is formed.

Further, the third layer may be still the other one layer of the layer on which gate electrodes GE1 and GE2 of transistors are formed, the layer on which source electrodes and drain electrodes SD1, SD2, SD3, and SD4 of transistors are formed, the layer on which an intermediate electrode CNE is formed, and the layer on which an anode electrode ANO is formed.

As described above, in the display device according to another example embodiment of the present disclosure, sub lines having a higher linear resistance are connected without passing through the contact hole so that a linear resistance increasing when the lines are connected is minimized. In contrast, sub lines having a lower linear resistance are connected through the contact hole to increase linear resistance when the lines are connected.

Accordingly, in the display device according to another example embodiment of the present disclosure, the deviation in the linear resistance of the constant power lines disposed in the vicinity of the optical area may be reduced. Accordingly, a bias voltage, a reset voltage, or an initialization voltage which is a uniform constant power may be applied to a plurality of pixels disposed on both sides of the optical area to more effectively ensure a luminance uniformity of the optical area.

The example embodiments of the present disclosure can also be described as follows:

According to an aspect of the present disclosure, a display device includes a display panel including an active area in which one or more optical areas are disposed; and one or more sensor modules overlapped with the optical area, the optical area is divided into a pixel area in which a plurality of pixels is disposed and a transmissive area through which light of the one or more sensor modules passes, and among a plurality of constant power lines configured to apply at least one constant power to the plurality of pixels disposed in the pixel area, adjacent constant power lines may be connected.

The plurality of constant power lines may include a plurality of main lines disposed at the outside of the active area; and a plurality of sub lines which is branched from at least one of the plurality of main lines to be connected to the plurality of pixels.

Among the plurality of sub lines, adjacent sub lines may be connected by a connection line.

The plurality of main lines may include a first main line disposed at one side of the active area; and a second main line disposed at the other side of the active area and the plurality of sub lines may include a plurality of first sub lines branched from the first main line and a plurality of second sub lines branched from the second main line.

When a length of the plurality of first sub lines is longer than a length of the plurality of second sub lines, adjacent first sub lines, among the plurality of first sub lines, may be connected and the plurality of second sub lines is separated from each other.

when the optical area is disposed to be adjacent to the other side of the active area, adjacent first sub lines, among the plurality of first sub lines, may be connected to each other and the plurality of second sub lines is separated from each other.

A first sub line, among the plurality of first sub lines, which does not extend to the transmissive area may be in contact with a second sub line, among the plurality of second sub lines, which does not extend to the transmissive area.

The adjacent sub lines and the connection line may be disposed on the same layer or different layers.

Sub lines having a first linear resistance, among the plurality of sub lines, may be connected by a first connection line disposed on a different layer from the sub lines having the first linear resistance, sub lines having a second linear resistance, among the plurality of sub lines, is connected by a second connection line disposed on the same layer as the sub lines having the second linear resistance, and the first linear resistance is lower than the second linear resistance.

Each of the plurality of pixels may include a light emitting diode, and a pixel circuit connected to the light emitting diode, and the pixel circuit may include a driving transistor configured to supply a driving current to the light emitting diode; a bias transistor configured to apply a bias voltage to a first electrode of the driving transistor; a reset transistor configured to apply a reset voltage to an anode electrode of the light emitting diode; and an initialization transistor configured to apply an initialization voltage to a gate electrode of the driving transistor.

The at least one constant power which is applied to the plurality of pixels may be at least one of the bias voltage, the reset voltage, and the initialization voltage.

The plurality of transistors included in the pixel circuit may include both a p-type transistor and an n-type transistor.

Some of the plurality of first sub lines may extend to the transmissive area, and the other of the plurality of first sub lines may not extend to the transmissive area.

Some of the plurality of second sub lines may extend to the transmissive area, and the other of the plurality of second sub lines may not extend to the transmissive area.

The one or more optical areas may be disposed in a center of the active area.

A length of the plurality of first sub lines may be equal to a length of the plurality of second sub lines.

Although example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The scope of protection of the present disclosure should be construed based on the following claims, and all technical features within the scope of equivalents thereof should be construed as being included within the scope of the present disclosure.

What is claimed is:

1. A display device, comprising:
a display panel including an active area in which one or more optical areas are disposed; and
one or more sensor modules overlapped with the one or more optical areas,
wherein the one or more optical areas are divided into a pixel area in which a plurality of pixels is disposed and a transmissive area through which light of the one or more sensor modules is to pass, and
wherein among a plurality of constant power lines configured to apply at least one constant power to the plurality of pixels disposed in the pixel area, adjacent constant power lines are connected to each other.

2. The display device according to claim 1,
wherein the plurality of constant power lines includes:
a plurality of main lines disposed at an outside of the active area; and
a plurality of sub lines which is branched from at least one of the plurality of main lines to be connected to the plurality of pixels.

3. The display device according to claim 2,
wherein among the plurality of sub lines, adjacent sub lines are connected by a connection line.

4. The display device according to claim 2,
wherein the plurality of main lines includes:
a first main line disposed at one side of the active area; and
a second main line disposed at another side of the active area; and
the plurality of sub lines includes:
a plurality of first sub lines branched from the first main line; and
a plurality of second sub lines branched from the second main line.

5. The display device according to claim 4,
wherein when a length of the plurality of first sub lines is longer than a length of the plurality of second sub lines, adjacent first sub lines, among the plurality of first sub lines, are connected, and the plurality of second sub lines is separated from each other.

6. The display device according to claim 4,
wherein when the one or more optical areas are disposed to be adjacent to the another side of the active area, adjacent first sub lines, among the plurality of first sub lines, are connected to each other, and the plurality of second sub lines is separated from each other.

7. The display device according to claim 4,
wherein a first sub line, among the plurality of first sub lines, which does not extend to the transmissive area is in contact with a second sub line, among the plurality of second sub lines, which does not extend to the transmissive area.

8. The display device according to claim 3,
wherein the adjacent sub lines and the connection line are disposed on a same layer.

9. The display device according to claim 3,
wherein the adjacent sub lines and the connection line are disposed on different layers.

10. The display device according to claim 2,
wherein sub lines having a first linear resistance, among the plurality of sub lines, are connected by a first connection line disposed on a different layer from the sub lines having the first linear resistance,
wherein sub lines having a second linear resistance, among the plurality of sub lines, are connected by a second connection line disposed on a same layer as the sub lines having the second linear resistance, and
wherein the first linear resistance is lower than the second linear resistance.

11. The display device according to claim 1,
wherein each of the plurality of pixels includes:
a light emitting diode, and a pixel circuit connected to the light emitting diode, and
wherein the pixel circuit includes:
a driving transistor configured to supply a driving current to the light emitting diode;
a bias transistor configured to apply a bias voltage to a first electrode of the driving transistor;
a reset transistor configured to apply a reset voltage to an anode electrode of the light emitting diode; and
an initialization transistor configured to apply an initialization voltage to a gate electrode of the driving transistor.

12. The display device according to claim 11,
wherein the at least one constant power which is to be applied to the plurality of pixels is at least one of the bias voltage, the reset voltage, and the initialization voltage.

13. The display device according to claim 11,
wherein a plurality of transistors included in the pixel circuit includes the driving transistor, the bias transistor, the reset transistor, and the initialization transistor, and
wherein the plurality of transistors included in the pixel circuit includes both a p-type transistor and an n-type transistor.

14. The display device according to claim 4,
wherein some of the plurality of first sub lines extend to the transmissive area, and the other of the plurality of first sub lines do not extend to the transmissive area.

15. The display device according to claim 4,
wherein some of the plurality of second sub lines extend to the transmissive area, and the other of the plurality of second sub lines do not extend to the transmissive area.

16. The display device according to claim 4,
wherein the one or more optical areas are disposed in a center of the active area.

17. The display device according to claim 16,
wherein a length of the plurality of first sub lines is equal to a length of the plurality of second sub lines.
